(19) United States
(12) Patent Application Publication
(10) Pub. No.: US 2010/0148628 A1
(43) Pub. Date: Jun. 17, 2010

(54) PIEZO ACTUATOR WITH PROTECTIVE RESISTOR

(76) Inventors: Thomas Pauer, Freiberg (DE); Friedrich Boecking, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/088,284

(22) PCT Filed: Aug. 15, 2006
(86) PCT No.: PCT/US06/65325

§ 371 Date: Mar. 27, 2008

(30) Foreign Application Priority Data
Sep. 27, 2005 (DE) 10 2005 046 118.2

(51) Int. Cl. H01L 41/09; H01L 41/083

(52) U.S. Cl. 310/317; 310/366

(57) ABSTRACT

Piezoactuator comprising a multiplicity of piezolayers, between each of which a layer electrode is arranged, the layer electrodes being alternately connected to a respective connection electrode. A protective resistor is provided between at least one connection electrode and the layer electrodes connected to said connection electrode.

The invention relates to a piezoelectric actuator, of the kind used for instance as a final control element in injection systems for internal combustion engines.

### PRIOR ART

From the prior art, ceramic piezoelectric actuators are known, in which the piezoelectric effect is utilized to move components. German Patent DE 199 28 177 C2, for instance, shows a piezoelectric actuator which comprises a ceramic piezoelectric body. The piezoelectric body is composed of a multiplicity of piezoelectric layers, between which a respective layer electrode is disposed. The layer electrodes are connected in alternation to a connection electrode, so that directly adjacent layer electrodes are each connected to different connection electrodes. If an electrical direct voltage is applied between the two connection electrodes, an electrical field is created between the layer electrodes. This causes the piezoelectric layers to change their thickness, so that overall, the length of the piezoelectric actuator changes. As a result, depending on the voltage set, the piezoelectric actuator can be used as a final control element, for instance in fuel injection systems. Because there are many layer electrodes spaced apart only slightly, a very strong electrical field can be applied without having to use an excessively high electrical voltage. This makes it possible, with only a relatively low control voltage, to produce a long stroke of the piezoelectric actuator.

The slight spacing of the layer electrodes from one another, which is generally in the range from 50 to 100 μm, however, is also a weak point of this piezoelectric actuator concept. The layer electrodes comprise a metal, such as silver or silver palladium, and this metal has a certain diffusion mobility inside the ceramic piezoelectric layers. Hence with time, it can happen that between two adjacent layer electrodes, from diffusion of metal layer electrode material, a jumper link is created and hence a short circuit between the two connection electrodes. Since the connection electrodes are normally electrically insulated from one another, a very strong current then flows through this jumper link, which on the one hand means a voltage loss and on the other causes major heating in that region. This heating increases the damage and can finally lead to destruction of the piezoelectric actuator.

### ADVANTAGES OF THE INVENTION

The piezoelectric actuator of the invention has the advantage over the prior art that even if a short circuit is created between two layer electrodes, it will still function. This is attained by providing that between at least one of the connection electrodes and the respective layer electrodes, protective resistors are provided. These resistors are dimensioned such that whenever a jumper link is created between two layer electrodes, the high leakage current now flowing causes the respective protective resistor to melt. As a result, the electrical connection between the defective layer electrode and the affected connection electrode is interrupted, and thus the applicable layer electrode is no longer connected to the connection electrode, and hence the piezoelectric layer located between them is also no longer exposed to the electrical field, but the remaining layer electrodes still function as before. This plays almost no role in the total stroke of the piezoelectric actuator, since in piezoelectric actuators of the kind used for instance in injectors for direct-injection internal combustion engines, several hundred piezoelectric layers and hence also several hundred layer electrodes are provided; thus even if some layers fail, the piezoelectric actuator can control the injector without problems.

Advantageous refinements of the subject of the invention are possible by provisions of the dependent claims. In an advantageous feature, the applicable protective resistor is embodied inside the layer electrode, so that the connection electrodes and rest of the geometry of the piezoelectric actuator need not be changed. Advantageously, the protective resistor is disposed inside the layer electrode and is for instance embodied in striplike form; the strip is embodied relatively close to the connection electrode, or at the edge of the layer electrode toward the connection electrode. The strip comprises a material which has a suitable electrical resistance and thus forms the protective resistor. Either one or a plurality of strips may be provided.

Advantageously, the protective resistor can be formed by a granular, piezoelectrically active material, and the grains are coated with a metal layer. The electrical conduction comes about inside this granular, piezoelectrically active material as a result of this metal coating, and the magnitude of the resistance is adjustable by way of the thickness of the metal layer. If the current through this protective resistor exceeds a certain level, then the metal with which the grains are coated melts and becomes capable of flowing, so that finally the electrical resistance is interrupted. The metal coating of the grains is preferably of the same material as the layer electrodes.

The protective resistor inside the layer electrode can also be formed by resistor bridges, so that in one strip, one or more resistor bridges are embodied that form the protective resistor. By way of the width and length of these resistor bridges, the protective resistor can also be adjusted. It is also possible to form the protective resistors by providing that between the connection electrodes and the layer electrode, metal resistor bridges are provided whose width is selected such that the electrical resistance is within the desired range. Such an arrangement is advantageous above all in the case of cylindrical piezoelectric actuators, in which the connection electrodes extend within the interior. In this case, radially extending, riblike connections with the layer electrodes may be provided, which form the protective resistor.

In a further advantageous feature, the connection electrodes are embodied as helically coiled wire, which inside the piezoelectric actuator makes a connection with the layer electrodes. The helically coiled wire may have a point-type contact with the layer electrodes such that as a result a suitable protective resistor is formed.

### DRAWINGS

In the drawings, various exemplary embodiments of the piezoelectric actuator of the invention are shown.

FIG. 1 shows a piezoelectric actuator of rectangular cross section, of the kind known from the prior art;

FIG. 2 is a substitute circuit diagram for a piezoelectric actuator of the invention that has suitable protective resistors;

FIG. 3a and FIG. 3b show two adjacent layer electrodes of a piezoelectric actuator of the invention of rectangular cross section;

FIG. 4a and FIG. 4b also show two adjacent layer electrodes of a rectangular piezoelectric actuator, in which the protective resistors are embodied differently;

FIG. 5 shows an enlarged view of a protective resistor of the kind that may be provided inside the layer electrode;

FIG. 6 shows a further exemplary embodiment, in which the piezoelectric actuator has a rectangular cross section but has cylindrical connection electrodes;

FIG. 7 is a cross section through a piezoelectric actuator of FIG. 6;

FIG. 8 shows a cylindrical piezoelectric actuator with connection electrodes located inside it;

FIG. 9a and FIG. 9b show two layer electrodes of the cylindrical piezoelectric actuator of FIG. 8;

FIG. 10 shows, as a further exemplary embodiment, a layer electrode of the kind that can be used in a cylindrical piezoelectric actuator;

FIG. 11 shows an internally located connection electrode, of the kind that can be used in a cylindrical piezoelectric actuator;

FIG. 12 shows a cylindrical piezoelectric actuator with two layer electrodes, shown as examples, and a helical connection electrode that is used for this kind of piezoelectric actuator;

FIG. 13 shows the helical connection electrode with a coating;

FIG. 14 is a section through the connection electrode of FIG. 13 taken along the line A-A; and

FIG. 15 is a further cross section, corresponding to the view in FIG. 14, in which suitable protective resistors are provided.

### DESCRIPTION OF THE EXEMPLARY EMBODIMENTS

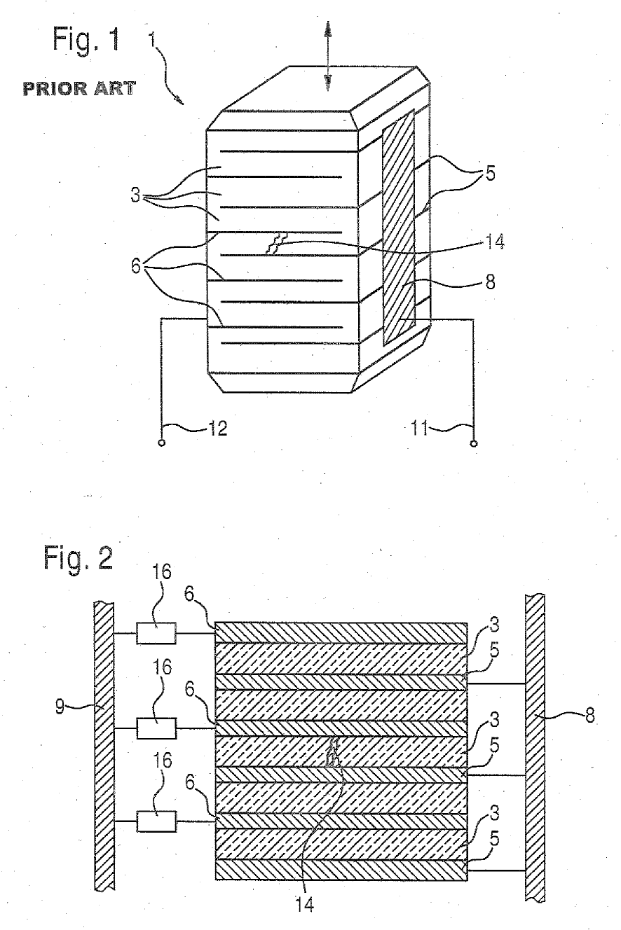

FIG. 1 shows a piezoelectric actuator 1, of the kind known from the prior art, and which has a rectangular cross section with beveled edges. The piezoelectric actuator 1 has a multiplicity of piezoelectric layers 3, which are made from a piezoelectrically active ceramic material. Between each of the piezoelectric layers 3, a respective metal layer electrode 5, 6 is provided; the various adjacent layer electrodes 5, 6 are electrically insulated from one another by the piezoelectric layers 3 located between them. Half of the layer electrodes 5 are connected to a first connection electrode 8, while the respective adjacent connection electrodes 6 are connected to a second connection electrode 9. The connection electrodes 8, 9 are applied here to the surface of the piezoelectric actuator 1 and are connected electrically conductively to the respective layer electrodes 5, 6. The connection electrodes 8, 9 have a flexibility so great that despite the change in length of the piezoelectric actuator 1, an electrical connection with the respective layer electrodes 5, 6 always remains. The connection electrodes 8, 9 are connected to electrical terminals 11, 12, with which an electrical voltage can be applied between the connection electrodes 8, 9.

By the application of an electrical voltage between the connection electrodes 8, 9, an electrical field is created between the layer electrodes 5, 6, which penetrates the piezoelectric layers 3. Depending on the magnitude of the electrical voltage and hence of the electrical field, the thickness of the piezoelectric layers 3 and thus the total length of the piezoelectric actuator 1 change. This makes it possible with the piezoelectric actuator 1 to move a corresponding final control element very quickly and also very precisely.

The layer electrodes 5, 6 are of a metal, such as silver or silver palladium; within the ceramic comprising the piezoelectric layers 3, this metal has a certain mobility. Especially when the piezoelectric actuator 1 has been in operation for a relatively long time, this can mean that metal dissolves out of the layer electrodes 5, 6 and forms a jumper link 14 between two adjacent layer electrodes 5, 6. This kind of jumper link 14 causes a short circuit between two adjacent layer electrodes 5, 6, so that then a correspondingly strong current flows through the jumper link 14. This causes locally severe heating of the piezoelectric actuator 1 and thus fusing of the metal layer electrodes 5, 6, which finally causes the destruction of the piezoelectric actuator 1.

To avert this destruction of the piezoelectric actuator 1, the invention provides that protective resistors 16 are disposed between the connection electrodes 5, 6 and the piezoelectric layer 3, and these protective resistors act as a safety fuse. FIG. 2 shows a substitute circuit diagram for this, in which the layer electrodes 5, 6 and the connection electrodes 8, 9 are shown. Between the connection electrode 9 and the layer electrodes 6, a respective protective resistor 16 is provided, which is dimensioned such that on the one hand it limits the current, when a jumper link 14 is created between two layer electrodes 5, 6, but on the other, if a persistently high current is flowing through the jumper link 14, it melts and thus interrupts the electrical contact between the defective layer electrode 6 and the connection electrode 9. As a result, the electrical connection between the jumper link 14 and the layer electrode 9 is also interrupted, so that the defective layer electrodes 5, 6 are no longer connected to the electrical power supply. The piezoelectric layer 3 located between them, because of the missing electrical field, no longer has any change in thickness, but since there are typically 200 piezoelectric layers 3, the failure of individual piezoelectric layers has is of negligible significance for the overall function of the piezoelectric actuator 1.

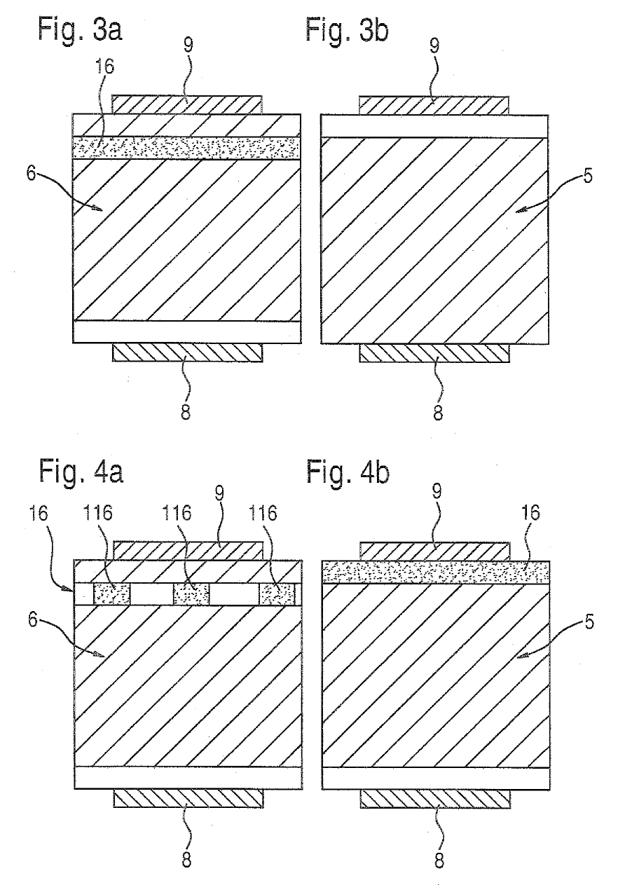

FIG. 3a shows a layer electrode 6 of the invention, in which the protective resistor 16 is embodied of strips inside the layer electrode 6. FIG. 3b shows the adjacent layer electrode 5, which is connected directly to the connection electrode 8, without a protective resistor. Since the protective resistor 16 here is integrated directly into the layer electrode 6, no change ensues in the piezoelectric actuator 1 in terms of its geometric dimensions, so that the connection electrodes 8, 9 as well as the installation conditions need not be changed.

FIG. 4a shows an alternative embodiment of the layer electrode 6 with protective resistors 16, which are formed here by resistor bridges 116. These resistor bridges, as before, comprise the granular, piezoelectrically active material, with the advantage here that there is an additional dimensioning option for the protective resistor by way of the width of the resistor bridges 116. FIG. 4b, in an alternative embodiment of the layer electrode of FIG. 3a, shows a protective resistor 16, embodied here at the edge of the layer electrode 6 and connected directly to the connection electrode 9. The mode of operation of the protective resistor 16 here, however, is identical to that of the protective resistor as shown in FIG. 3.

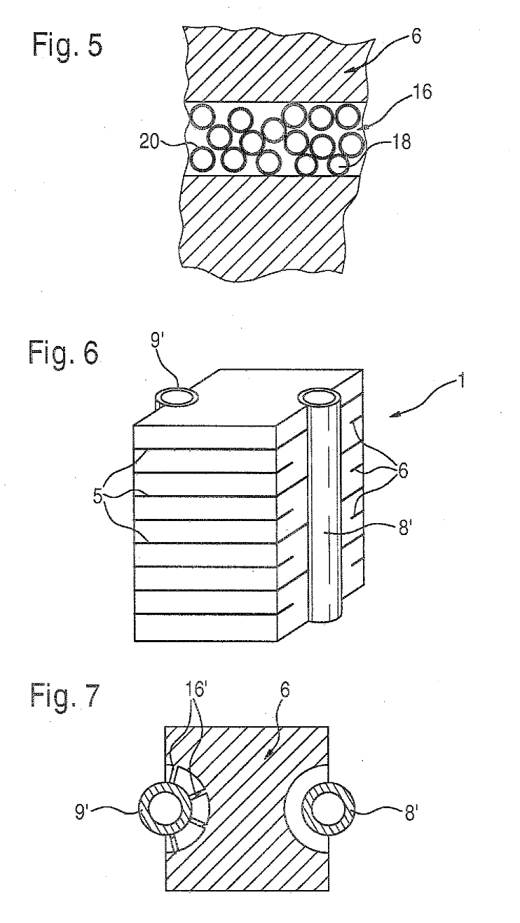

The protective resistor 16, which is provided as a strip in the layer electrode 6, can be formed for instance by granular, piezoelectrically active material, as shown in an enlarged view in FIG. 5. The individual grains 18 are provided with a metal coating 20, which forms the electrically conductive path inside the layer electrode 6. if an excessively high current through this metal coating 20 then occurs, the coating melts, and the metal moves inside the protective resistor 16 in such a way that after a certain time, the protective resistor disconnects the layer electrode 6 from the connection electrode 9.

FIG. 6 shows a further piezoelectric actuator 1, which likewise has a rectangular cross section. The connection electrodes 8′, 9′ are embodied here as metal tubules, which protrude into a semicircular recess in the piezoelectric actuator 1. FIG. 7 shows a cross section through the piezoelectric actuator of FIG. 6, in which a layer electrode 6 is shown. The connection electrode 9′ is connected to the layer electrode 6 via protective resistors 16′, which are formed by riblike connections. Depending on the number and width of the riblike connections that form the protective resistors 16′, a protective resistor of more or less large size results between the connection electrode 9′ and the layer electrode 6. The layer electrode 6 here is electrically disconnected from the second connection electrode 8′, while the layer electrode 5 located above or below it is connected to the connection electrode 8′ in the known manner.

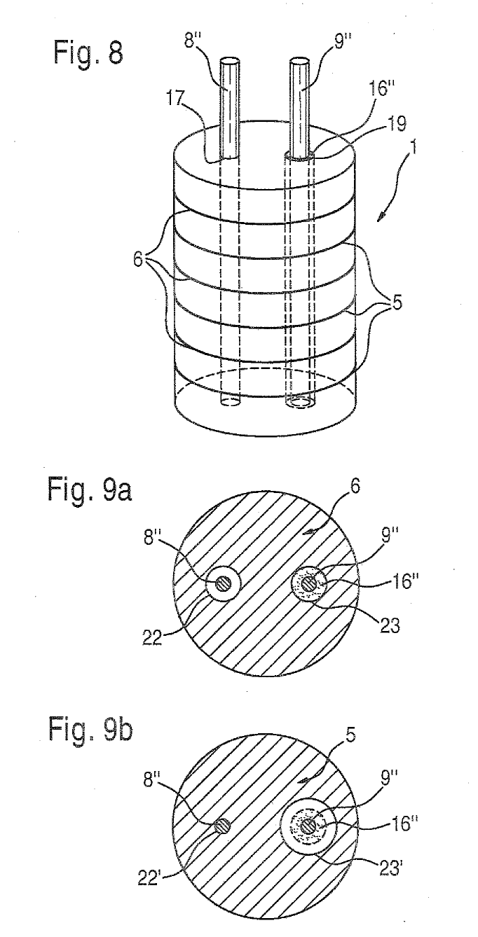

FIG. 8 shows a piezoelectric actuator 1, which has a circular cross section. Two bores 17, 19 are embodied in the piezoelectric actuator 1, in each of which one connection electrode 82′, 9″ is disposed. These are connected in a known manner to the layer electrodes 5, 6, and the protective resistor 16″ is formed here as a result of the fact that the connection electrode 9″ is sheathed by a material having a suitable electrical resistance, as a result of which in the final analysis the electrical contact between the connection electrode 9″ and the layer electrodes 5 comes about. FIG. 9a to illustrate this shows a layer electrode 6, which is connected to the connection electrode 9″. The layer electrode 6 has two recesses 22, 23, so that no electrical connection is brought about between the connection electrode 8″ and the layer electrode 6. By means of the material that surrounds the connection electrode 9″, a protective resistor 16″ is formed, by way of which the layer electrode 6 is connected to the connection electrode 9″. The material that surrounds the connection electrode 9″ may for instance likewise have a granularity comprising metal-coated ceramic grains, of the kind shown in FIG. 5. However, still other materials, which have a suitably high specific resistance, are also conceivable.

FIG. 9b shows the layer electrode 5 located above or below, which is connected to the connection electrode 8″. By means of a suitably large recess 23′, this layer electrode is not connected to the connection electrode 9″.

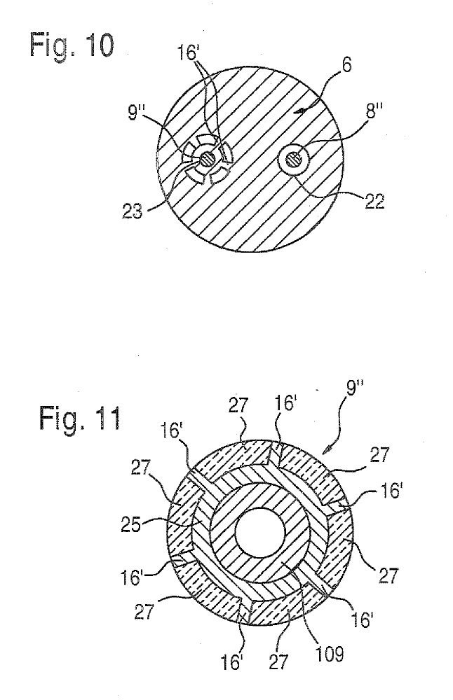

FIG. 10 shows a further exemplary embodiment of a layer electrode 6, of a kind that can be provided in a round piezoelectric actuator. The protective resistor 16′ is formed here by resistor bridges, which are provided inside the layer electrode 6 and by way of which the electrical connection with the connection electrode 9″ is formed. In this case, the sheathing of the connection electrodes 9″ is omitted. The layer electrode 5 located correspondingly above or below is connected to the connection electrode 8″ and is insulated from the connection electrode 9″.

FIG. 11 shows a further exemplary embodiment, in which the protective resistor is integrated into the connection electrodes 9″. The connection electrode 9″ here comprises a metal tube 109, which is surrounded by a metal coating 25 that has riblike everted features pointing outward, which form the protective resistor 16′. Between the protective resistors 16′, an electrically insulating, preferably ceramic material 27 is provided, so that in the final analysis, the metal tube 109 is connected to the respective layer electrode 5, 6 via the protective resistors 16′. The circular piezoelectric actuator 1 can thus be constructed in the known manner and connected to the connection electrodes 8, 9 requiring only that one of the connection electrodes be replaced by a connection electrode 9″ of FIG. 11.

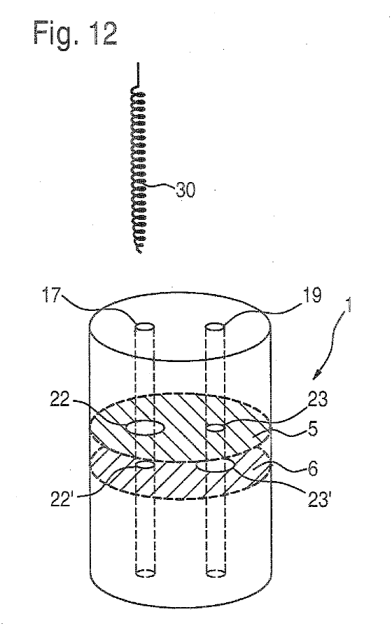

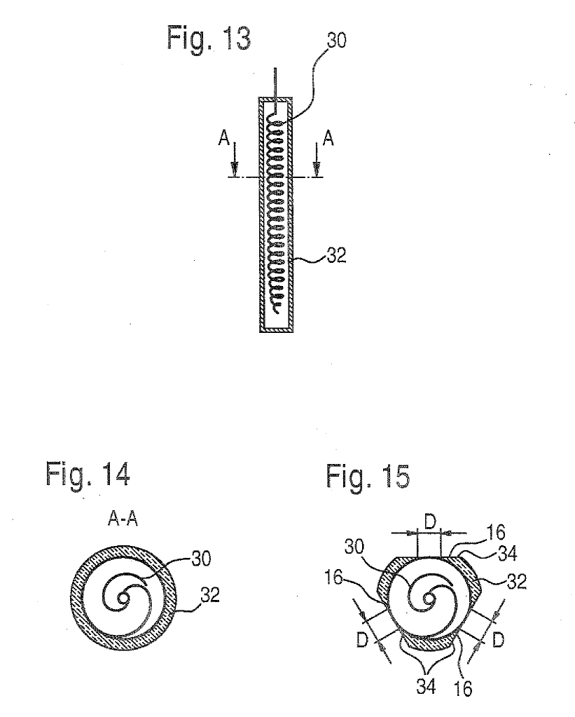

FIG. 12 shows a further exemplary embodiment of a piezoelectric actuator 1 of circular cross section. The piezoelectric actuator 1 has two bores 17, 19, which receive the connection electrodes. As an example, two layer electrodes 5, 6 are shown here, which are extended in alternation in a known manner to the wall of the bores 17, 19 and thus are contactable at that point. A spring electrode 30, which comprises a helically coiled wire, is inserted into the bores 17, 19. To form the transition resistors 16, the helical spring electrode 30 is coated with a ceramic layer 32, as shown in FIG. 13. In cross section, as shown in FIG. 14, the ceramic coating 32 that surrounds the helical spring electrode 30 on all sides is seen. To form a suitable transition resistor that acts as a protective resistor 16, the ceramic coating 32 is removed by means of a superficial polished section 34, creating a bare place of width D, as shown in FIG. 15. As a result, the helical spring electrode 30 touches the respective layer electrodes 5, 6 in pointlike fashion, which given suitable dimensioning produces a transition resistor that acts as a protective resistor 16.

The protective resistors 16 should preferably be dimensioned such that in response to an excessively elevated current, they heat up and melt accordingly, even before the current that in a short circuit flows between two layer electrodes 5, 6 causes the destruction of the piezoelectric actuator 1. Besides the embodiment of the protective resistors 16 inside the layer electrodes 5, 6 by means of a granular ceramic compound that is coated with metal, it is for instance also possible for the layer electrode 5, 6 to be suitably doped in one region, in order to obtain a suitable electrical resistance there.

1-13. (canceled)

14. A piezoelectric actuator comprising a multiplicity of piezoelectric layers, a layer electrode disposed between each adjacent pair of piezoelectric layers, the layer electrodes connected in alternation with a respective connection electrode, and protective resistors between at least one connection electrode and the layer electrodes connected to this connection electrode.

15. The piezoelectric actuator as defined by claim 14, wherein the layer electrodes are formed by a metal layer between two respective piezoelectric layers.

16. The piezoelectric actuator as defined by claim 14, wherein the protective resistor is disposed inside the layer electrode.

17. The piezoelectric actuator as defined by claim 15, wherein the protective resistor is disposed inside the layer electrode.

18. The piezoelectric actuator as defined by claim 16, wherein the protective resistor forms at least one strip inside the layer electrode.

19. The piezoelectric actuator as defined by claim 17, wherein the protective resistor forms at least one strip inside the layer electrode.

20. The piezoelectric actuator as defined by claim 16, wherein the protective resistor is formed by granular, piezoelectrically active material, and the grains are coated with a metal coating.

21. The piezoelectric actuator as defined by claim 17, wherein the protective resistor is formed by granular, piezoelectrically active material, and the grains are coated with a metal coating.

22. The piezoelectric actuator as defined by claim 18, wherein the protective resistor is formed by granular, piezoelectrically active material, and the grains are coated with a metal coating.

23. The piezoelectric actuator as defined by claim 19, wherein the protective resistor is formed by granular, piezoelectrically active material, and the grains are coated with a metal coating.

24. The piezoelectric actuator as defined by claim 20, wherein the metal coating of the grains comprises the same material as the metal layer electrodes.

25. The piezoelectric actuator as defined by claim 21, wherein the metal coating of the grains comprises the same material as the metal layer electrodes.

26. The piezoelectric actuator as defined by claim 16, wherein the protective resistor is formed by one or more resistor bridges.

27. The piezoelectric actuator as defined by claim 17, wherein the protective resistor is formed by one or more resistor bridges.

28. The piezoelectric actuator as defined by claim 14, wherein the metal connection electrodes are embodied in rodlike form.

29. The piezoelectric actuator as defined by claim 28, wherein at least one connection electrode is connected to the associated layer electrodes by essentially radially extending, riblike connections, and the riblike connections form the protective resistors.

30. The piezoelectric actuator as defined by claim 28, wherein at least one connection electrode extends in the interior of the piezoelectric actuator.

31. The piezoelectric actuator as defined by claim 14, wherein the piezoelectric actuator comprises at least one spring electrode as its connection electrode, which spring electrode is embodied as a helically coiled wire and is disposed in the interior of the piezoelectric actuator in a receiving bore.

32. The piezoelectric actuator as defined by claim 31, wherein the protective resistors are formed by the point-type contact between the spring electrode and the layer electrodes.

33. The piezoelectric actuator as defined by claim 14, wherein the protective resistors are heated to such an extent that they melt and thus interrupt the flow of current if a maximum allowable current is exceeded.
